(19) United States
(12) Patent Application Publication
(10) Pub. No.: US 2026/0018226 A1
(43) Pub. Date: Jan. 15, 2026

(54) STROBELESS DYNAMIC RANSOM ACCESS MEMORY (DRAM) DATA INTERFACE WITH DRIFT TRACKING CIRCUITRY

(71) Applicant: Rambus Inc., San Jose, CA (US)

(72) Inventor: Dongyun Lee, Sunnyvale, CA (US)

(21) Appl. No.: 18/995,095

(22) PCT Filed: Aug. 13, 2023
(86) PCT No.: PCT/US2023/030123

§ 371 Date: Jan. 15, 2025

Related U.S. Application Data
(60) Provisional application No. 63/398,817, filed on Aug. 17, 2022.

(51) Int. Cl. G11C 29/02

(52) U.S. Cl. CPC G11C 29/023; G11C 29/028

(57) ABSTRACT

Memory devices, modules, controllers, systems and associated methods are disclosed. In one embodiment, an integrated circuit (IC) memory chip is disclosed. The IC memory chip includes clock receive circuitry to receive a clock signal and command/address (C/A) receive circuitry to time reception of C/A signals using the clock signal. Data receive circuitry receives a first data burst from a first data path. Calibration circuitry sets an initial sampling phase for data reception timing of the first data burst relative to the clock signal. Timing circuitry tracks drift in the data reception timing using phase information from at least one toggling edge of the data burst and adjusts the data reception timing based on the phase information.

### TECHNICAL FIELD

The disclosure herein relates to memory systems, memory controllers, memory devices, and associated methods.

### BRIEF DESCRIPTION OF THE DRAWINGS

Embodiments of the disclosure are illustrated by way of example, and not by way of limitation, in the figures of the accompanying drawings and in which like reference numerals refer to similar elements and in which:

FIG. 1 illustrates one embodiment of a memory system that employs a memory controller, and at least one memory device.

FIG. 2 illustrates a pair of data bursts associated with separate data DQ paths that may be combined to form a pseudo-differential preamble for the drift tracking circuit of FIG. 1.

FIG. 3 illustrates one embodiment of a drift tracking circuit for the memory system shown in FIG. 1.

FIG. 4 illustrates a high-level flowchart for one embodiment of a method of training the memory system of FIG. 1.

FIG. 5 illustrates relative timings for various memory operations performed by the memory system of FIG. 1 during a coarse write training step of FIG. 4.

FIG. 6 illustrates relative timings for various training steps performed by the memory device architecture of FIG. 1 during a fine write training process of FIG. 4 involving an oversampling technique.

FIG. 7 illustrates a flowchart of steps employed for one embodiment of the oversampling technique of FIG. 6.

FIG. 8 illustrates relative timings for various memory operations performed by the memory system of FIG. 1 during a read training step of FIG. 4.

FIG. 9 illustrates a further embodiment of a drift tracking circuit in the form of a locked-loop circuit for the memory system of FIG. 1.

FIG. 10 illustrates a flowchart of steps for one embodiment of tracking drift using the locked-loop circuit of FIG. 9.

### DETAILED DESCRIPTION

Memory devices, modules, controllers, systems and associated methods are disclosed. In one embodiment, an integrated circuit (IC) memory chip is disclosed. The IC memory chip includes clock receive circuitry to receive a clock signal and command/address (C/A) receive circuitry to time reception of C/A signals using the clock signal. Data receive circuitry receives a first data burst from a first data path. Calibration circuitry sets an initial sampling phase for data reception timing of the first data burst relative to the clock signal. Timing circuitry tracks drift in the data reception timing using phase information from at least one toggling edge of the data burst and adjusts the data reception timing based on the phase information. Some embodiments described herein may transmit and/or receive the data burst with a preamble such that the phase information is associated with at least one toggling edge of the preamble. Other embodiments may, during a preamble interval, implement the data receive circuitry to receive a first single-ended preamble signal of the first data burst from the first data path and a second single-ended preamble signal of a second data burst from a second data path, and combine the first single-ended preamble signal and the second single-ended preamble signal to form a pseudo-differential signal. In some embodiments, mode register storage stores a value representing a duration and a pattern of the preamble interval. By tracking phase drift in data reception timing using the phase information from at least one toggling edge of a data burst, a pin count and associated chip surface area of a memory device may be significantly reduced, thereby correspondingly reducing the size of memory modules within, for example, a data center environment.

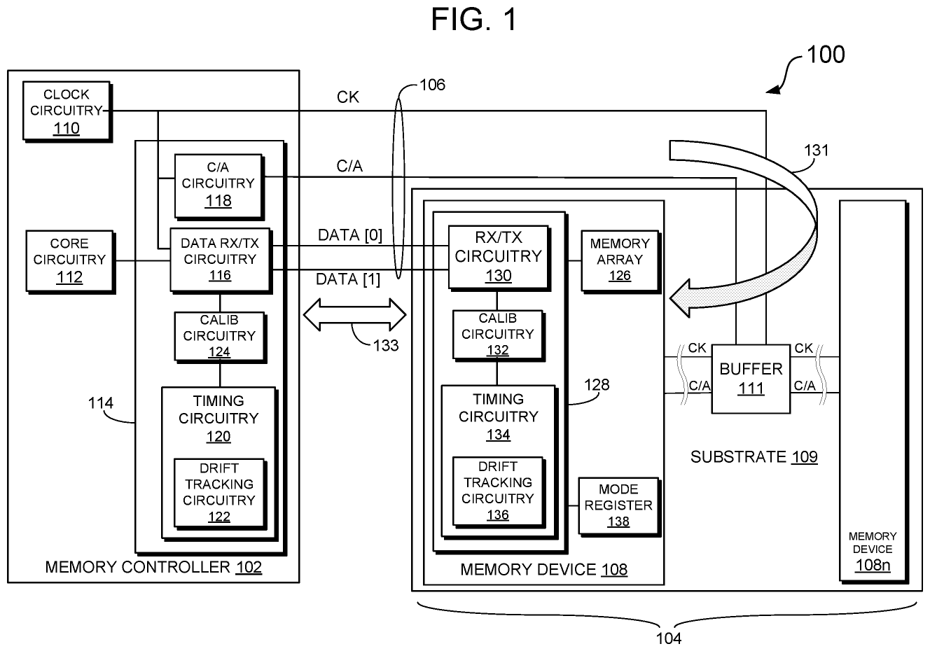

Referring now to FIG. 1, a memory system, generally designated 100, is shown that includes a memory controller 102 coupled to memory 104 via signaling media 106. For one embodiment, the memory controller 102 is a dynamic random access memory (DRAM) controller, with the memory 104 realized as one or more DRAM memory devices 108. In some embodiments, the memory controller 102 and memory devices 108 may be embodied as integrated circuits, or chips. Other embodiments may employ the memory controller as a memory control circuit in a host central processing unit (not shown). Specific embodiments for the DRAM memory controller 102 and memory 104 may be compliant with various DRAM standards, including double data rate (DDR) variants, low power (LPDDR) versions, high bandwidth (HBM), and graphics (GDDR) types. Other embodiments may include multi-chip modules that, for example, employ stacked memory die, or stacked packages. Such embodiments may be used with the memory devices 108. Additional embodiments may stack memory die and logic die together in a common package, or in separate packages stacked upon each other. Yet other embodiments may employ multiple memory devices on a substrate 109 in a memory module configuration for high-capacity applications.

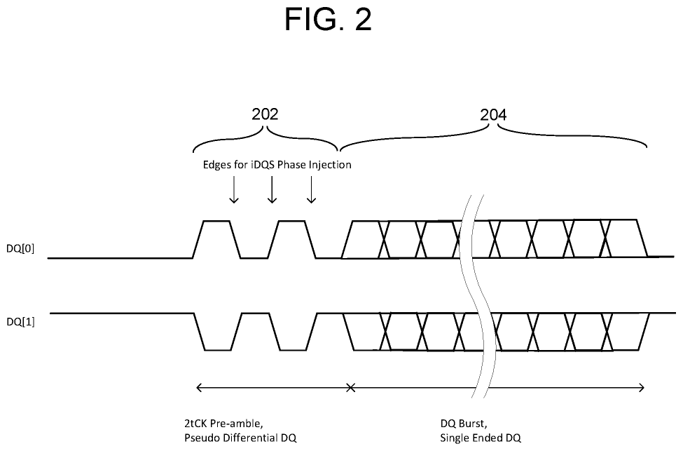

Further referring to FIG. 1, for one embodiment, the memory controller 102 includes clock circuitry 110 for generating and transmitting a system clock CK that is used by the memory system as a reference clock signal for system synchronization purposes. The memory controller 102 also includes logic core circuitry 112 and a signaling interface 114. The signaling interface 114 is coupled to the clock circuitry 110 to time transmission and reception of data signals transferred with strobeless data transceiver (Rx/Tx) circuitry 116 and command/address signals transmitted with command/address (C/A) interface circuitry 118. For one embodiment, the strobeless data transceiver circuitry 116 transfers streams of data in the form of single-ended data bursts along respective data paths, such as DATA [0] and DATA [1], which are unaccompanied by any source-synchronous strobe signals. For one specific embodiment, described more fully below and shown in FIG. 2, each data burst waveform may include a preamble component with toggling edges that may be used to time reception of the data burst.

With continued reference to FIG. 1, one embodiment of the memory controller 102 includes timing circuitry 120 to manage various relative timings associated with the data transceiver circuitry 116. The timing circuitry 120 generates an internal strobe signal based on the clock signal CK that is used to sample read data bursts received by the data transceiver circuitry 116 from the memory 104. Since the strobe signal is generated internal to the memory controller 102, and not received as an external signal accompanying the read data, there is no need for a separate strobe input/output (I/O) transmitter/receiver in the data transceiver circuitry 116 or associated strobe path in the signaling media 106. This significantly reduces the memory controller pin count, and correspondingly reduces I/O power consumption. For some embodiments, the timing circuitry 120 employs drift tracking circuitry 122 to track drift in read data reception timing, specifically the phase relationship between the internally-generated strobe signal and the system clock signal CK. Specific embodiments of the drift tracking circuitry 122 are described more fully below in the context of similar circuitry employed in the memory devices 108. Calibration circuitry 124 manages read and write timing calibration operations involving the data transceiver circuitry 116 and the timing circuitry 120 as described more fully below.

Further referring to FIG. 1, each of the memory devices 108 includes memory array circuitry 126 including an array of storage cells, and memory interface circuitry 128 that communicates with the signaling interface 114 of the memory controller 102. For one embodiment, the memory interface circuitry 128 includes transceiver (Rx/Tx) circuitry 130 that, for write operations, receives C/A, clock, and write data signals from the memory controller 102 via the data paths DATA [0], DATA [1], a clock path CK from a buffer 111, and a command/address path C/A from the buffer 111. For some embodiments, the buffer takes the form of a registering clock driver (RCD) and receives the clock signal CK and C/A signals and distributes them to the memory devices 108. In other embodiments, the buffer 111 may take the form of a clock buffer that receives and distributes the clock signals to the memory devices 108, but does not receive and distribute the C/A signals, which are routed to bypass the buffer 111. For read operations, the memory interface circuitry 128 transmits read data to the memory controller 102 via the data paths DATA [0], DATA [1]. While only two data paths are shown and described, for some embodiments there may be upwards of eighty or more point-to-point data paths dedicated for data transfers between the memory controller 102 and the memory devices 108.

In some embodiments, the clock path CK and the C/A path C/A may be routed in a fly-by fashion from the memory controller 102 to the multiple memory devices 108 via the buffer 111. One example of a fly-by signaling path length from the memory controller 102 to the memory device 108 is shown generally by arrow 131. In contrast, the data paths such as DATA [0] and DATA [1] may be routed in a point-to-point fashion between the memory controller 102 and the memory devices 108 (or possibly including an intermediate point-to-point path involving a data buffer). One example of a point-to-point path length between the memory controller 102 and the memory device 108 is generally represented by arrow 133. The differences in routing lengths between the fly-by paths and the point-to-point data paths may cause timing errors such as phase skew, transient phase jumps and phase drift between the various clock, data and C/A signals.

To minimize timing error that may result from the differing path lengths of fly-by and point-to-point signaling paths, one embodiment of the memory device 108 employs calibration circuitry 132 to cooperate with the calibration circuitry 124 of the memory controller 102 in managing initial timing calibration operations during an initialization process. The memory device 108 also includes timing circuitry 134 to perform timing adjustments resulting from the timing calibration operations. In some embodiments, the timing circuitry 134 employs drift tracking circuitry 136 to track drift in write data reception timing during a normal mode of operation that is distinct from a calibration mode of operation.

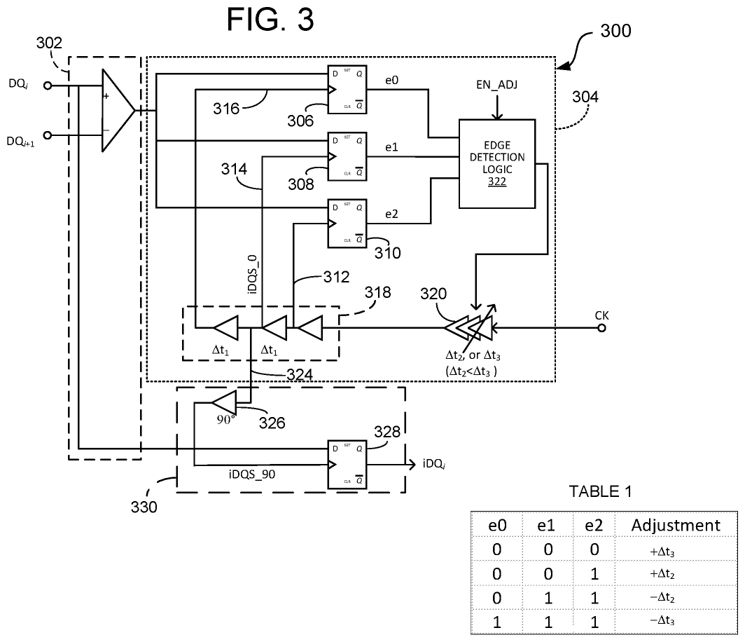

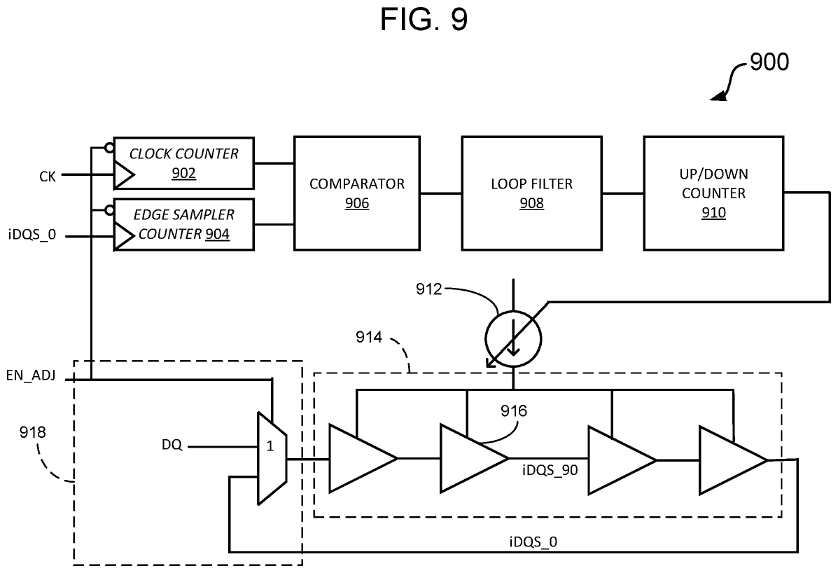

As noted above, for one embodiment, each data burst waveform transferred between the memory controller interface 116 and memory device data interface 130 includes a preamble component that may be used to time reception of the data components included in the data burst. Depending on the situation, a given data burst length may include sixteen, thirty-two or more bits of data. FIG. 2 illustrates one example of a first single-ended data burst, identified as DQ [0]. The data burst includes a preamble component, at 202, that exhibits a preamble interval of two clock cycles. Immediately following the preamble interval is a data component of the data burst waveform, at 204, involving a stream of data bits. The toggling edges of the preamble may be edge-sampled by oversampling circuitry (such as an embodiment shown in FIG. 3), or alternatively fed to a locked-loop circuit (such as an embodiment shown in FIG. 9) in an effort to periodically and/or continuously correct for phase drift of the internally-generated strobe signal with respect to the clock signal. For some embodiments, storage in the form of mode register circuitry 138 (FIG. 1) resides in each memory device 108 to store a value representing a duration and a pattern of the preamble interval. For some embodiments, noise effects resulting from jitter or other forms of interference (ISI) may be effectively cancelled by temporarily combining one or more pairs of single-ended data bursts to form a pseudo-differential signal during the preamble interval duration. The resulting signal provides a clean waveform which may be used in oversampling or phase injection techniques, described more fully below, in order to correct for timing drift. Following the preamble interval duration, the respective data burst paths return to their single-ended configurations.

While the preamble component of FIG. 2 is shown as leading the data burst, the preamble component may be inserted anywhere in the data burst waveform. This may be advantageous in situations where a maximum interval constraint is applied to manage accumulated drift over time, allowing for a preamble insertion anywhere during a data burst to reset the accumulated drift to zero.

Referring now to FIG. 3, for one embodiment, the drift tracking circuitry 136 takes the form of an oversampler circuit 300. The oversampler circuit 300 generally takes multiple edge samples of at least one toggling edge of a data burst (such as the pseudo-differential preamble component described above) to generate edge information, and then based on the edge information, adjusts a sampling phase of an internally-generated strobe signal. The oversampler circuit 300 includes an input 302 to receive an initial sequence of edges of a data burst. The initial sequence of edges may be edges of a data bit, or edges of a preamble component of the data burst, or pseudo-differential edges of a combined pair of preamble components such as that shown in FIG. 2.

Further referring to FIG. 3, the oversampler circuit 200 includes a clock phase adjustment path 304 that employs a plurality of edge samplers 306, 308 and 310. Each of the edge samplers receive a toggling edge of the data burst, and sample the edge in accordance with respective equal and progressively-delayed timing signals fed along timing paths 312, 314, and 316. A tapped delay line 318 generates each of the timing signals based on an externally-generated clock signal CK that is phase-adjusted by variable delay circuitry 320. Edge detection logic 322 evaluates respective edge samples e0, e1 and e2, in response to a control signal EN_ADJ (which is based on a write latency parameter t_{WL}), to determine a relative early/late relationship of the edge samples with respect to the toggling edge of the data burst. Based on the determined early/late relationship, the edge detection logic 32 adjusts the variable delay circuitry 320 to feed a phase adjusted clock signal to the tapped delay line 318 and correspondingly adjust the timings of the edge sampling signals to minimize the error of the edge samples. For one embodiment, the adjustment to the variable delay circuitry 320 may be made in accordance with TABLE 1 of FIG. 3. Thus, in a situation where all of the edge samples indicate a logic “0”, a large timing adjustment is made to the phase of the clock signal to correspondingly shift the edge sampling timing signals by a relatively large timing increment in order to find the toggling edge of the data burst. As a transition of the edge is found (identified by adjacent edge samples indicating a “0” and a “1”), smaller timing adjustments are made to the clock signal CK, in an effort to align the middle edge sampling phase to the toggling edge of the data burst.

With continued reference to FIG. 3, for one specific embodiment, the tapped delay line 318 generates edge timing signals that are each progressively delayed by an equal increment Δt₁ relative to the clock signal CK. An internal strobe path 324 taps the output of the second delay element of the tapped delay line 318, the edge sampling timing signal iDQS_0, corresponding to e1, and includes an additional delay element 326 to further delay the tapped signal by 90 degrees, resulting in an internal strobe signal iDQS_90 that is used to sample the data signal DQ via a data sampler 328. The internal strobe path 324 and the data sampler 328 cooperate to form a data sampling path 330 that is separate from the clock phase adjustment path 304. In some embodiments, since the clock phase adjustment path 304 is separate from the data sampling path 330, equalization circuitry such as a decision feedback equalizer (DFE) (not shown) may be incorporated into the data sampling path 330 to reduce inter-symbol interference.

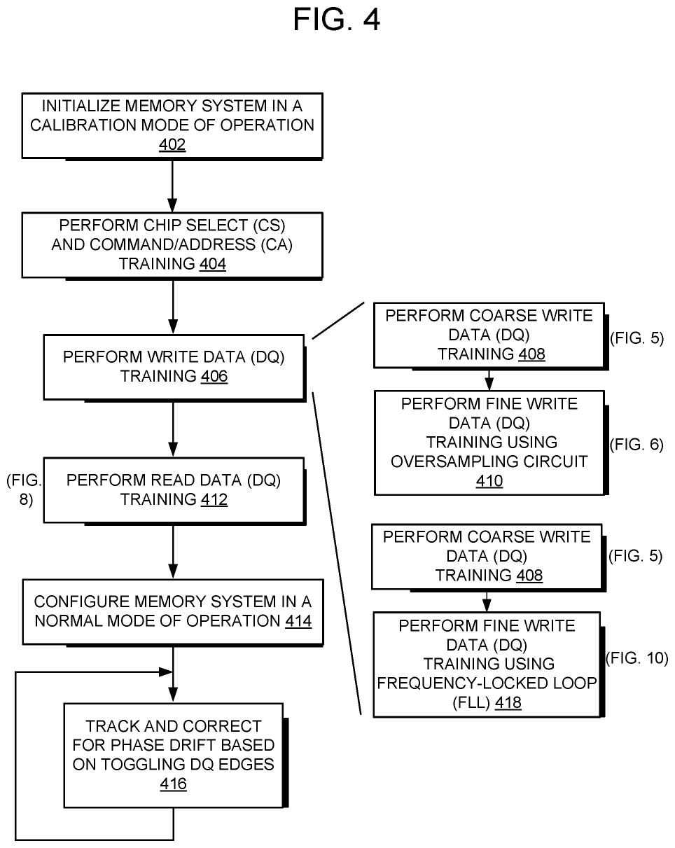

For one embodiment, prior to operating the memory system of FIG. 1, the internally-generated strobe signals undergo a training process to accurately align the internal strobe signal of the memory controller 102 to read data, and to accurately align the internal strobe signal of each memory device 108 to write data. FIG. 4 illustrates one embodiment of the training process which begins by initializing the memory system 100 into a training or calibration mode of operation, at 402. The training mode of operation activates the calibration circuitry 118 and 132 in the memory controller 102 and each of the memory devices 108. The calibration circuitry may then generate and/or expect to receive specific training data patterns, rather than real data, for various calibration steps as described below. Once placed in the training mode of operation, the system performs a chip select (CS) and command/address (C/A) training process, at 404, to more accurately align the CS and C/A signals to the system clock signal CK.

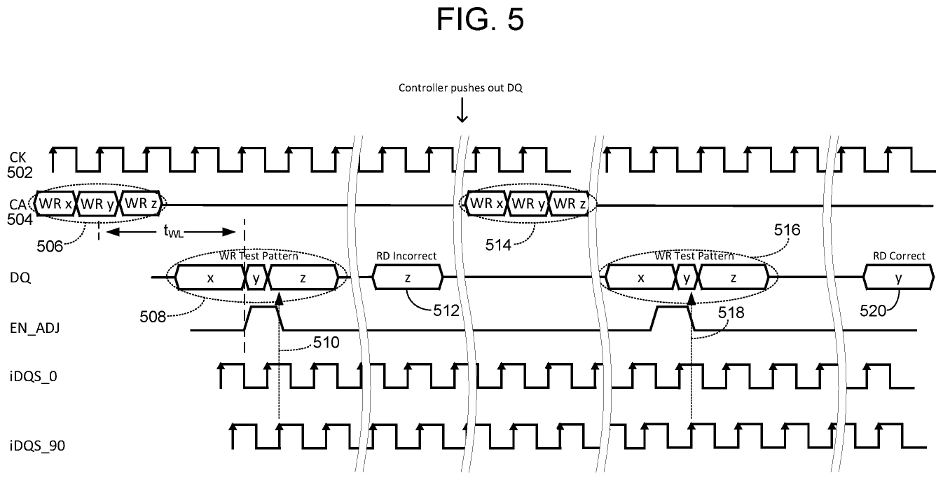

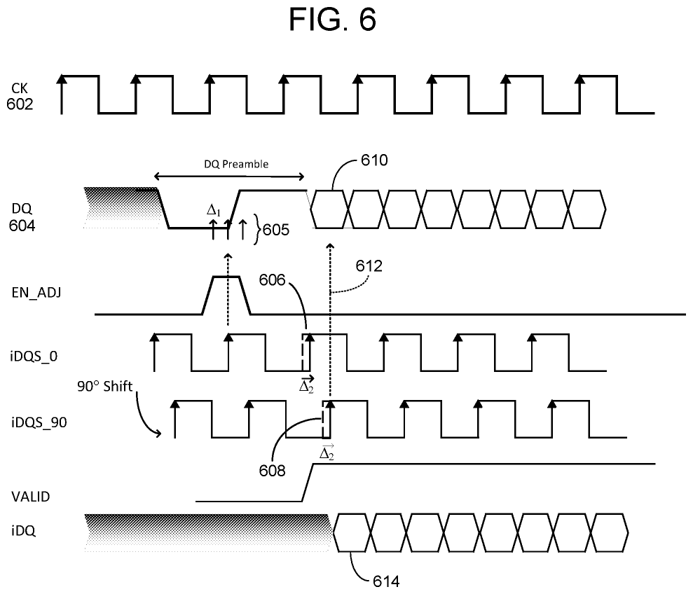

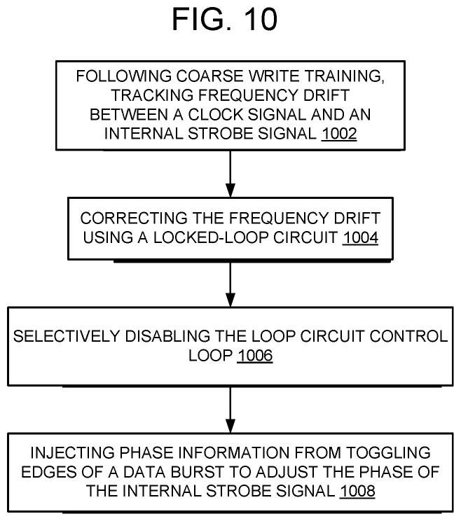

Further referring to FIG. 4, once the CS and C/A training process is finished, the memory system performs a write data (DQ) training process, at 406. For one embodiment, this involves first carrying out an approximate, or “coarse” write data training, such as aligning an internally-generated strobe signal to a data signal at approximately a unit interval (UI) level of granularity, at 408 (and discussed further with respect to FIG. 5). This may then be followed by a more accurate “fine” write data training, at 410, such as aligning the internally-generated strobe signal to the data signal at a fractional UI level of granularity (and discussed more fully with respect to FIG. 6). In another embodiment, the write data training 406 involves performing the coarse write data training 408, followed by a fine write training using a locked-loop circuit, at 418, to inject phase information from toggling edges of a data burst and verifying an accurately aligned internal strobe phase with respect to the data (discussed more fully with respect to FIG. 10).

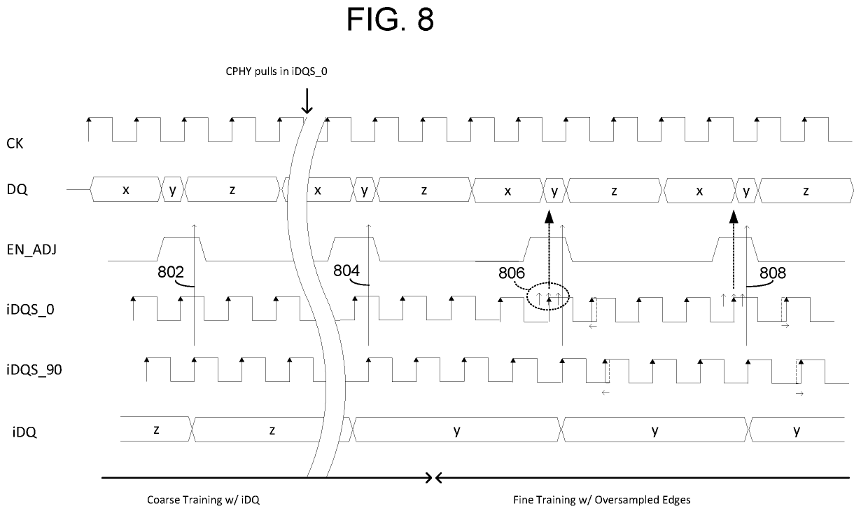

With continued reference to FIG. 4, once the write data training at 406 is complete, the memory system 100 performs a read data training process, at 412 (more fully discussed with reference to FIG. 8). When the read training process finishes, the memory system 100 may then enter a normal mode of operation, at 414, involving real data transfers between the memory controller 102 and the memory devices 108. While operating in the normal mode of operation, the drift tracking circuitry in the memory controller and each of the memory devices periodically and/or continuously tracks and corrects for phase drift, at 416, based on toggling edges of real read and write data bursts that may or may not include preamble signal components.

FIG. 5 illustrates a timing diagram corresponding to one embodiment of the initial “coarse” write data training block 408 of FIG. 4. The top waveform at 502 corresponds to the system clock signal CK as-received by a memory device 108. Just below the clock waveform CK is shown a command waveform CA, at 504, as-received by the memory device 108. The command waveform shows a first pattern of write commands, at 506, for respective “x”, “y” and “z” data, at 508. The corresponding “x”, “y” and “z” data is received by the memory device data interface circuitry 130 after a write latency interval t_{WL} following the respective command signals. FIG. 5 shows the corresponding write latency timing for the “y” data bit and corresponding command. The write data is then sampled by a rising edge of the internally-generated strobe signal iDQS_90 when an enable signal EN_ADJ is valid (high), at 510. The enable signal timing is based on the write latency parameter t_{WL}, and based on the clock CK timing. The coarse training process, as managed by the memory device calibration circuitry, provides for feedback being sent back to the memory controller 102 along a feedback path, such as the bidirectional data DQ path, to verify whether the correct data was sampled within a UI level of timing granularity (a UI corresponding to a timing interval where the data bit is valid). The timing diagram of FIG. 5 is truncated in the sense that it omits sampling of the “x” and “z” data, and focuses only on the “y” data sampling. As shown in FIG. 5, at 512, the feedback from the return DQ data path identifies data “z” as being sampled by the internally-generated sampling signal iDQS_90 rather than data “y”.

Further referring to FIG. 5, once the memory controller 102 receives the feedback from the memory device 108 and performs a comparison between the sampled “z” data versus the expected “y” data, the calibration circuitry 124 of the memory controller 102 pushes-out, or delays the timing of the data Rx/Tx circuitry 116 by a coarse timing amount, such as a UI interval, so that a subsequently dispatched calibration data pattern may be received at the memory device a UI interval later than the previous calibration data, and more closely align with the internally-generated edge sampling signal iDQS_0. A second pattern of calibration write commands is then sent to the memory device 108, at 514, followed by the respective calibration data, at 516, which has been pushed-out or delayed by a UI interval. The data is sampled, at a correct sampling point 518, and the resulting information sent back to the controller, at 520, confirming a successful coarse write timing alignment.

As explained above and shown in FIG. 4, once the coarse training is finished for one embodiment, a fine training is performed to more accurately align a sampling edge of the internal strobe signal iDQS_90 to an optimum valid point of the data with a maximum amount of margin on each side of the sampling point. FIG. 6 illustrates a timing diagram corresponding to a fine training process that uses the oversampling circuitry 300 of FIG. 3. The timing diagram of FIG. 6 provides the system clock signal CK as the top waveform at 602, and a data burst waveform DQ at 604. The data burst waveform follows a write command for the data (not shown) by the write latency timing parameter t_{WL}, which initiates the enable signal EN_ADJ to the edge detection logic 322 (FIG. 3) of the oversampling circuit 300. For one embodiment, the data burst waveform DQ includes the preamble component 202 described with respect to FIG. 2.

Further referring to FIG. 6, with the oversampling interval enabled by the signal EN_ADJ, a plurality of edge samples are taken by the multiple edge samplers 306, 308 and 310 (FIG. 3), at 605, to generate the edge information e0, e1 and e2. As explained earlier with respect to FIG. 3, should all of the edge samples indicate a “0”, then the toggling preamble edge was completely missed by the edge samplers. A sampled “1” adjacent to a “0” by any two adjacent edge values indicates the phase at which the toggling preamble edge lies. The edge detection circuitry then feeds an adjustment to the variable delay circuitry 320 to delay or advance the clock signal CK that feeds the tapped delay line 318, by an adjustment value, such as Δt₂. The adjustment causes corresponding delays in the edge sampling signal iDQS_0, at 606, and the internal strobe signal iDQS_90, at 608, (which is based on the edge sampling signal iDQS_0). With the next bit of the data burst, at 610, and the internally-generated strobe signal finely adjusted, the data is then sampled at or near the center of the data eye, at 612, to produce valid data, at 614.

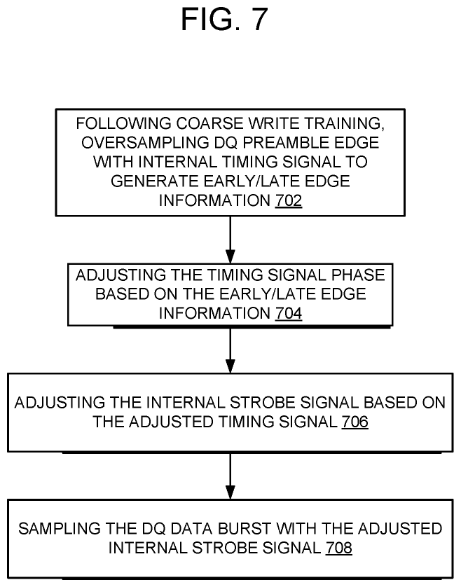

FIG. 7 illustrates a high-level flowchart of steps consistent with the above

description for carrying out one embodiment of the fine training process. At 702, following the coarse write training described above, the data burst toggling preamble edge is oversampled with internal timing signals to generate early/late edge information. The timing signal phases are then adjusted, at 704, based on the early/late edge information. At 706, the internally-generated strobe signal is also adjusted based on the adjusted timing signals. The data burst following the preamble is then sampled, at 708, with the adjusted internally-generated strobe signal.

As explained with respect to FIG. 4, once the write timing training reaches completion, the memory system 100 performs the read training process 412 to align the internally-generated strobe signal of the memory controller to read data received by the memory controller from a memory device. FIG. 8 illustrates a timing diagram corresponding to one embodiment of the read training process which is handled similarly to the write training coarse/fine processes, but without the need for any feedback path from the memory device 108 since the memory controller 102 sets its own delays for the various timing signals. Thus, at 802, an initial sampling point to sample read data “y” is misaligned with data “z”, causing the memory controller to push the timing of the received read data by a UI interval (for example), where it may be more accurately sampled, at 804. The memory controller 102 may then carry out a fine training operation by, for example, oversampling the toggling edge of data “y”, at 806, resulting in a phase shift of the internally-generated edge sampling signal iDQS_0 to be phase-aligned with the toggling edge of data “y”, and correspondingly causing the internally-generated strobe signal iDQS_90 to be optimally-aligned with the valid portion of the data eye of data “y”, at 808.

In a further embodiment, a locked-loop circuit may be employed in the memory controller 102 and each memory device 108 to internally-generate the strobe signal for sampling the data bursts and to perform the write-related calibration and drift tracking functions described above. FIG. 9 illustrates one embodiment of a locked-loop circuit in the form of a frequency-locked loop (FLL) 900 that locks the clock signal CK frequency to the edge sampling iDQS_0 frequency. The FLL 900 includes a clock counter 902 to receive the clock signal CK and an edge sampling counter 904 to receive the edge sampling signal iDQS_0. The counters count the received edges of the respective clock CK and edge sampling iDQS_0 signals. A comparator 906 compares the edge counts and feeds a difference value to a loop filter 908. Based on various coefficients applied by the loop filter 908 to the difference value, an up/down count value is generated by up/down counter 910 and applied to an M-bit current digital-to-analog converter (DAC) 912. The DAC feeds a frequency adjustment signal to a current-controlled oscillator (CCO) 914 that employs a line of inverter elements 916 that cooperate to generate an output signal, iDQS_0, of a frequency that matches the input reference signal—here, the clock signal CK. The FLL also includes a selectively-enabled phase injection path 918, where the data burst preamble may be phase-injected into the CCO 914 to force an immediate alignment of the preamble toggling edge (upon which the internally-generated strobe timing is based) to iDQS_0. For one embodiment, the phase injection path 918 is enabled only during the phase adjustment window identified by a “valid” enable signal EN_ADJ.

FIG. 10 illustrates steps employed in one embodiment of a method of operation of the locked-loop circuit of FIG. 9. At 1002, following the coarse write training described above, the circuit tracks frequency drift between the clock signal CK and the internal strobe signal iDQS_90. The frequency drift is corrected using the control loop of the locked-loop circuit, at 1004. At 1006, in response to receiving the enable signal EN_ADJ, the loop circuit control loop is disabled, at 1006, and phase information from toggling edges of a data burst are injected into the CCO 914, at 1008, to forcibly align the phase of the internal strobe signal iDQS_90 to the toggling edges of the data burst.

For one embodiment, rather than performing drift tracking adjustments on each burst, the drift tracking adjustments occur within a certain number of bursts, assuming a small tracking error for each burst that accumulates upon each successive burst. A maximum number of bursts before a preamble is transmitted with a data burst may be based on the required size of the data eye opening in terms of UI, the burst length, and the ratio of the change in frequency for an incremental change in the least-significant-bit (LSB) of the frequency value to the nominal frequency.

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of the present invention. In some instances, the terminology and symbols may imply specific details that are not required to practice the invention. For example, any of the specific numbers of bits, signal path widths, signaling or operating frequencies, component circuits or devices and the like may be different from those described above in alternative embodiments. Also, the interconnection between circuit elements or circuit blocks shown or described as multi-conductor signal links may alternatively be single-conductor signal links, and single conductor signal links may alternatively be multi-conductor signal links. Signals and signaling paths shown or described as being single-ended may also be differential, and vice-versa. Similarly, signals described or depicted as having active-high or active-low logic levels may have opposite logic levels in alternative embodiments. Component circuitry within integrated circuit devices may be implemented using metal oxide semiconductor (MOS) technology, bipolar technology or any other technology in which logical and analog circuits may be implemented. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘<̅s̅i̅g̅n̅a̅l̅ n̅a̅m̅e̅>̅ ’) is also used to indicate an active low signal. The term “coupled” is used herein to express a direct connection as well as a connection through one or more intervening circuits or structures. Integrated circuit device “programming” may include, for example and without limitation, loading a control value into a register or other storage circuit within the device in response to a host instruction and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The term “exemplary” is used to express an example, not a preference or requirement.

While the invention has been described with reference to specific embodiments thereof, it will be evident that various modifications and changes may be made thereto without departing from the broader spirit and scope of the invention. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

In the claims:

1. An integrated circuit (IC) memory chip, comprising:
clock receive circuitry to receive a clock signal;
command/address (C/A) receive circuitry to time reception of C/A signals using the clock signal;
data receive circuitry to receive a first data burst from a first data path;
calibration circuitry to set an initial sampling phase for data reception timing of the first data burst relative to the clock signal; and
timing circuitry to track drift in the data reception timing using phase information from at least one toggling edge of the first data burst and to adjust the data reception timing based on the phase information.

2. The IC memory chip of claim 1, wherein:
the first data burst includes a preamble having a preamble interval; and
wherein the phase information is associated with at least one toggling edge of the preamble.

3. The IC memory chip of claim 2, wherein:
the data receive circuitry is to receive a second data burst from a second data path;
wherein during the preamble interval, the data receive circuitry is to receive a first single-ended preamble signal of the first data burst from the first data path and a second single-ended preamble signal of a second data burst from the second data path; and
wherein the first single-ended preamble signal and the second single-ended preamble signal are combined to form a pseudo-differential signal during the preamble interval.

4. The IC memory chip of claim 2, further comprising:
mode register storage to store a value representing a duration and a pattern of the preamble interval.

5. The IC memory chip of claim 1, wherein:
the timing circuitry includes an oversampling circuit to track the drift in the data reception timing.

6. The IC memory chip of claim 5, wherein the oversampling circuit comprises:
edge sampling circuitry to sample the at least one toggling edge of the first data burst to generate multiple edge samples that reflect edge error information; and
an internal strobe generation circuit to generate an internal strobe signal based on the clock signal to sample a valid portion of the first data burst, the internal strobe signal adjusted based on the edge error information.

7. The IC memory chip of claim 6, wherein:
the edge sampling circuitry defines a clock phase adjustment path;
the valid portion of the first data burst is sampled in a data sampling path that is separate from the clock phase adjustment path; and
wherein the memory IC chip further includes decision-feedback equalization (DFE) circuitry disposed in the data sampling path to correct for inter-symbol interference.

8. The IC memory chip of claim 1, wherein:
the timing circuitry includes a locked-loop circuit to track the drift in the data reception timing.

9. The IC memory chip of claim 8, wherein:
the locked-loop circuit exhibits a frequency that is locked to the clock signal, and a phase that is locked to the data reception timing.

10. The IC memory chip of claim 1, embodied as an IC dynamic random access memory (DRAM) chip.

11. A dynamic random access memory (DRAM) device, comprising:
clock receive circuitry to receive a clock signal;
command/address (C/A) receive circuitry to time reception of C/A signals using the clock signal; and
calibration circuitry to train timing of an internally-generated strobe signal to the clock signal, the calibration circuitry to
perform a first training for setting an initial sampling phase for the internally-generated strobe signal, the first training to train data reception timing of a first data pattern relative to the clock signal; and
perform a second sampling training to determine a second sampling phase adjustment to the initial sampling phase, the second sampling phase adjustment determined using phase information from at least one toggling edge of a first data burst and to adjust the data reception timing based on the phase information.

12. The DRAM device of claim 11, wherein:
the first data burst includes a preamble having a preamble interval; and
wherein the phase information is associated with at least one toggling edge of the preamble.

13. The DRAM device of claim 12, further comprising:
data receive circuitry to receive the first data burst from a first data path and a second data burst from a second data path;
wherein during the preamble interval, the data receive circuitry is to receive a first single-ended preamble signal of the first data burst from the first data path and a second single-ended preamble signal of a second data burst from the second data path; and
wherein the first single-ended preamble signal and the second single-ended preamble signal are combined to form a pseudo-differential signal during the preamble interval.

14. The DRAM device of claim 12, further comprising:
mode register storage to store a value representing a duration and a pattern of the preamble interval.

15. The DRAM device of claim 11, further comprising:
transmit circuitry to transmit feedback to a memory controller during the first training, the feedback indicating a relative alignment between the first data pattern and the internally-generated strobe signal; and
wherein the initial sampling phase is set based on the feedback.

16. The DRAM device of claim 11, further comprising:
an oversampling circuit to perform the Sine second sampling training.

17. (canceled)

18. A method of operating a dynamic random access memory (DRAM) device, comprising:
receiving a clock signal;
timing reception of command/address (C/A) signals using the clock signal; and
training timing of an internally-generated strobe signal to the clock signal, the training including:
performing a first training for setting an initial sampling phase for the internally-generated strobe signal, the first training to train data reception timing of a first data pattern relative to the clock signal; and
performing a second sampling training to determine a second sampling phase adjustment to the first-initial sampling phase, the second sampling phase adjustment determined using phase information from at least one toggling edge of a first data burst and to adjust the data reception timing based on the phase information.

19. The method of claim 18, wherein:
the first data burst includes a preamble having a preamble interval; and
wherein the phase information is associated with at least one toggling edge of the preamble.

20. The method of claim 19, further comprising:
receiving the first data burst from a first data path and a second data burst from a second data path;
wherein during the preamble interval, receiving a first single-ended preamble signal of the first data burst from the first data path and a second single-ended preamble signal of a second data burst from the second data path; and
combining the first single-ended preamble signal and the second single-ended preamble signal to form a pseudo-differential signal during the preamble interval.

21. The method of claim 20, further comprising:
retrieving a stored value from mode register storage representing a duration and a pattern of the preamble interval.
